(19) United States
(12) Patent Application Publication
(10) Pub. No.: US 2004/0263308 A1
(43) Pub. Date: Dec. 30, 2004

(54) INDUCTOR FORMED BETWEEN TWO LAYOUT LAYERS

(76) Inventors: Jay Yu, Taipei Hsien (TW); Jimmy Hsu, Taipei Hsien (TW); Nicole Li, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/605,521

(22) Filed: Oct. 6, 2003

(30) Foreign Application Priority Data
Jun. 11, 2003 (TW) 092115913

(51) Int. Cl. H01F 30/14

(52) U.S. Cl. 336/200; 336/10

(57) ABSTRACT

An inductor includes a first wiring layer, a second wiring layer, a first conductive trace, a second conductive trace, a third conductive trace, and a fourth conductive trace. The first conductive trace is on the first wiring layer and the second conductive trace is on the second wiring layer. The third conductive trace is parallel to the first conductive trace and is on the first wiring layer. The fourth conductive trace is parallel to the second conductive trace- and is on the second wiring layer. The first end of the first conductive trace is connected to the first end of the second conductive trace through a first via plug. The second end of the second conductive trace is connected to the first end of the third conductive trace through a second via plug. The second end of the third conductive trace is connected to the first end of the fourth conductive trace through a third via plug.

As wireless communication progresses, passive devices such as inductors, transformers, and capacitors widely used in circuit design for wireless communication are being integrated onto a chip. Inductors integrated onto the chip are applied to wireless integrated circuit design components such as low noise amplifiers (LNA), mixers, voltage controlled oscillators (VCO), and so on. However, the high power consumption of the chip may lower the quality level and increase the circuit design difficulties.

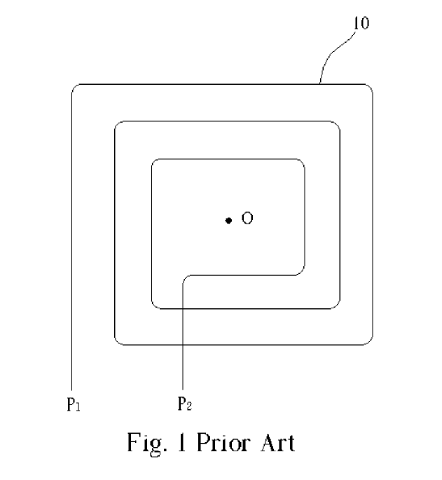

Please refer to FIG. 1 which is a layout diagram illustrating a conventional planar inductor 10 according to the prior art. As shown in FIG. 1, the planar inductor 10 is formed by a coil, which has two differential signal ends P1, P2 and spirals inwards around a point O from the outer end P1 to the inner end P2 to form a necessary number of loops and then exits the plane from the P2 end. Because the coil of the planar inductor 10 cannot directly overlap itself, the overlapping section of the coil in FIG. 1 is connected to another circuit board layer by a via plug connected to the P2 end. A major drawback of the planar inductor 10 according to the prior art is that the inductor consumes a large substrate area, increasing the cost and reducing the possibility of integrating it onto the chip. Reducing the distance of the inductor traces causes a narrower useful bandwidth. In addition, the quality factor of the planar inductor 10 and the resistance of the coil are inversely proportional. The longer the coil, the larger the resistance, and therefore, increased energy dissipation of the planar inductor 10 reduces the quality factor and it becomes difficult to apply such an inductor in wireless integrated circuit design.

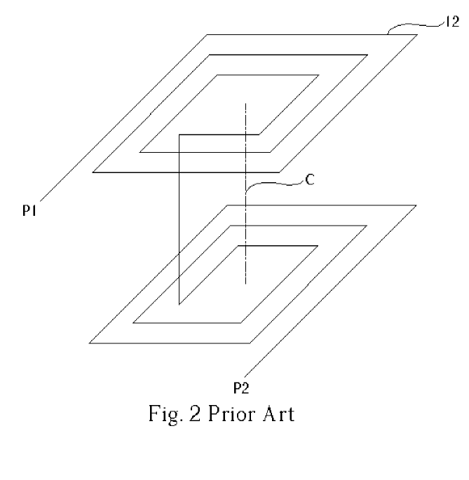

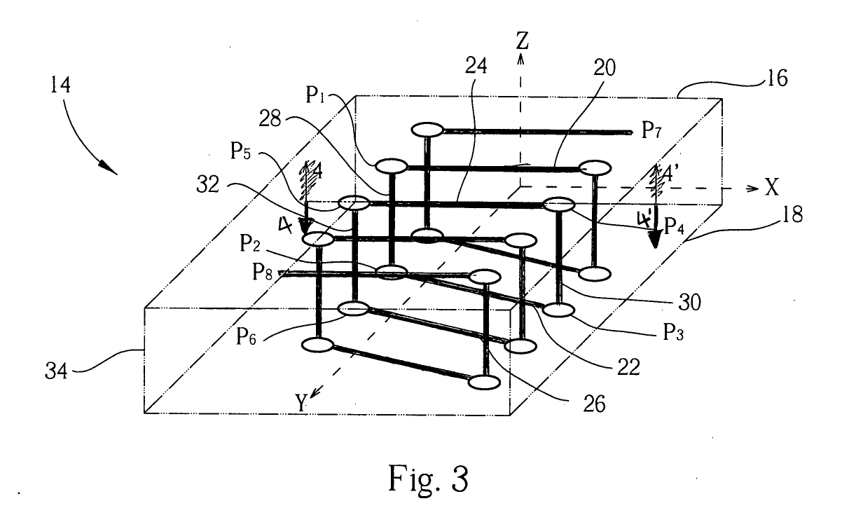

Please refer to FIG. 2. FIG. 2 is a layout diagram of a conventional two-level inductor 12 according to the prior art. In order to reduce layout area, as shown in FIG. 2, a two-level conductive coil is used to form the two-level inductor 12. The two-level inductor 12 includes two differential signal ends P1, P2 and spirals inwards around a line C from the P1 end to form a necessary number of loops. The coil is then connected to another circuit board layer by a via plug and then spirals outwards around the line C and ending at the P2 end. It is worth mentioning that current flowing in the two layered coils is in the same direction, which increases the mutual inductance of the two-level inductor 12. In other words, the current flows into the end P1 from the outer ring to the inner ring in a clockwise direction, connects to the second layer by the via plug, and similarly flows clockwise from the inner ring to the outer ring ending at the P2 end. Although the two-level inductor 16 reduces layout area and increases mutual inductance between the two conductive coils when compared with the planar inductor 10, common mode noise is not effectively reduced and results in a narrower utilized bandwidth.

Briefly summarized, an inductor includes a first wiring layer, a second wiring layer, a first conductive trace, a second conductive trace, a third conductive trace, and a fourth conductive trace. The first conductive trace is on the first layout layer and the second conductive trace is on the second layout layer. The third conductive trace is parallel to the first conductive trace and is on the first wiring layer. The fourth conductive trace is parallel to the second conductive trace and is on the second wiring layer. The first end of the first conductive trace is connected to the first end of the second conductive trace through a first via plug. The second end of the second conductive trace is connected to the first end of the third conductive trace through a second via plug. The second end of the third conductive trace is connected to the first end of the fourth conductive trace through a third via plug.

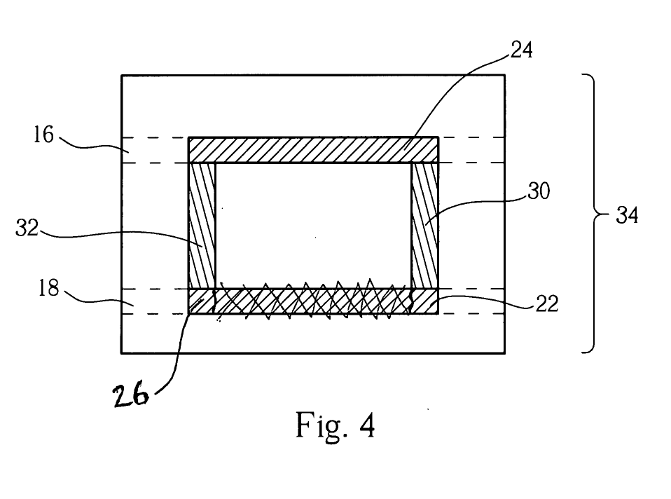

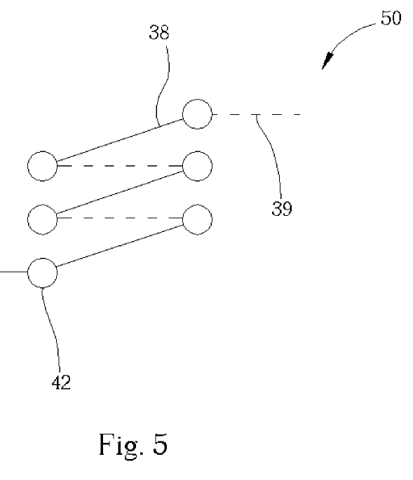

FIG. 5 to FIG. 8 illustrate four additional types of inductors according to the present invention.

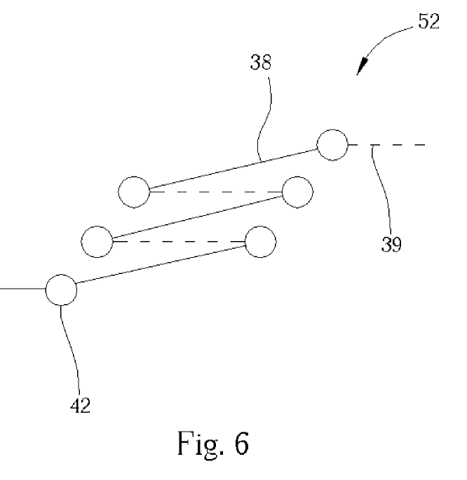

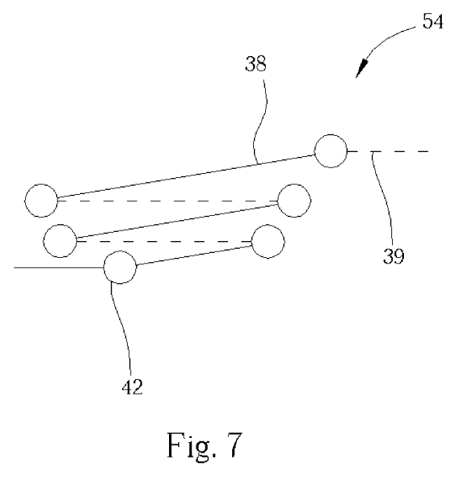

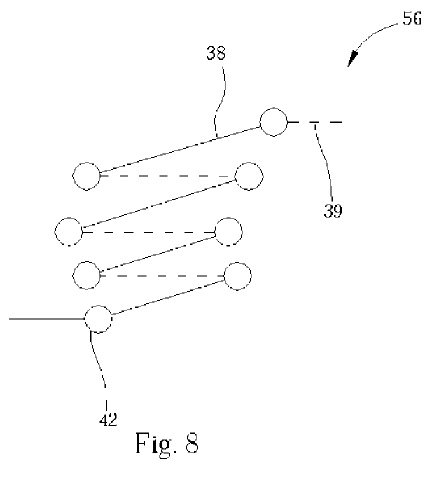

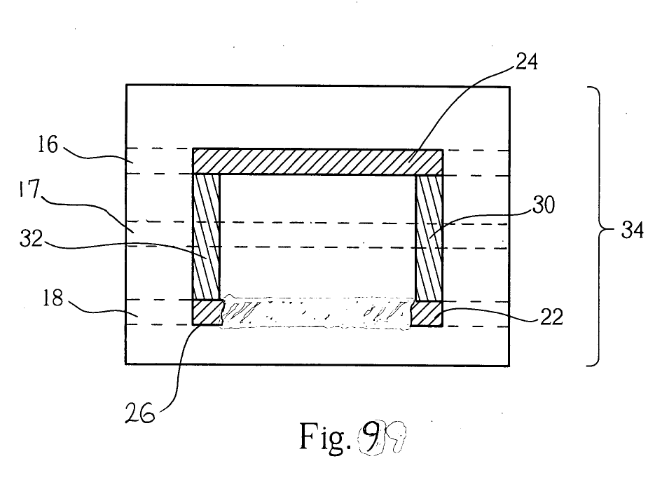

In order to comply with different layout requirements, the inductor 14 can be of varied forms. Please refer to FIG. 5 to FIG. 8 which illustrate four additional types of inductors 50, 52, 54, 56 according to the present invention. In FIG. 5 to FIG. 8, conductive traces 38, shown as solid lines, are formed on the first wiring layer 16 and conductive traces 39, shown as broken lines, are formed on the second wiring layer 18. As shown in FIG. 5 to FIG. 8, the conductive traces 38 of the inductors 50, 52, 54, 56 on the first wiring layer 16 are parallel to each other and the conductive traces 39 on the second wiring layer 18 are also parallel to each other. In FIG. 5 and FIG. 6, the via plugs 42 are positioned along two parallel lines, in FIG. 7 the via plugs 42 are aligned but are not positioned along two parallel lines, and in FIG. 8 the via plugs 42 are not aligned. Using these adaptations, the inductor 14 can differ in various forms to comply with the layout design requirements.

The inductor according to the present invention can be composed of multi-layered coils and can be manufactured by printed circuit board technology. The inductor includes a plurality of conductive layers, wherein each conductive layer includes a plurality of conductive traces arranged alternately, being isolated by a plurality of insulating layers. A plurality of via plugs perpendicular to the conductive traces is used for connecting the traces between the different layers. The magnetic field generated by the inductor is in parallel with the conductive layers. All multi-layered inductors having coils formed by conductive traces and via plugs are in the scope of the present invention.

1. A printed circuit inductor comprising:
a first conductive trace formed on a first wiring layer of a printed circuit board;
a second conductive trace formed on a second wiring layer of a printed circuit board, wherein the second layer is disposed below and parallel to the first layer, the layers being separated by an insulating material;
a third conductive trace formed on the first wiring layer and parallel to the first conductive trace;
a fourth conductive trace formed on the second wiring layer and parallel to the second conductive trace;
a first via plug directly connected to a first end of the first conductive trace and to a first end of the second conductive trace;
a second via plug directly connected to a second end of the second conductive trace and to a first end of the third conductive trace; and
a third via plug directly connected to a second end of the third conductive trace and a to first end of the fourth conductive trace.

2. The inductor of claim 1 wherein the first via plug is perpendicular to the first conductive trace, the second via plug is perpendicular to the second conductive trace, and the third via plug is perpendicular to the third conductive trace.

3. A printed circuit inductor comprising:
a plurality of conductive traces formed on a plurality of wiring layers of a printed circuit board, wherein the conductive element of the inductor is formed from interconnected conductive traces disposed on separate wiring layers, each conductive trace having at least an end disposed coincident with an end of a conductive trace disposed on a separate layer allowing interconnection by a via;
a plurality of insulating layers for isolating the conductive layers from each other; and
a plurality of via plugs each directly connecting the conductive traces on different conductive layers.

4. The inductor of claim 3 wherein the plurality of conductive layers is formed having two layers.

5. The inductor of claim 3 wherein the plurality of via plugs is perpendicular to the plurality of conductive layers.

6. The inductor of claim 3 wherein the magnetic field generated by the inductor is in parallel with the conductive layers.
